(19) United States
(12) Patent Application Publication
(10) Pub. No.: US 2013/0273814 A1
(43) Pub. Date: Oct. 17, 2013

(54) POLISHING APPARATUS AND POLISHING METHOD

(71) Applicant: EBARA CORPORATION, Tokyo (JP)

(72) Inventors: Yoichi Kobayashi, Tokyo (JP); Katsutoshi Ono, Tokyo (JP)

(73) Assignee: Ebara Corporation, Tokyo (JP)

(21) Appl. No.: 13/864,181

(22) Filed: Apr. 16, 2013

(30) Foreign Application Priority Data
Apr. 17, 2012 (JP) 2012-94114

(51) Int. Cl. H01L 21/302

(52) U.S. Cl. CPC H01L 21/302
USPC 451/6; 438/689

(57) ABSTRACT

A polishing apparatus polishes a substrate having a film formed thereon. A sensor is disposed in a polishing table that supports a polishing pad thereon. The polishing apparatus is configured to perform an idling process in which polishing of the substrate on the polishing pad does not progress substantially, while rotating the polishing table and the substrate. The sensor obtains the film thickness data, which varies in accordance with a thickness of the film, while the idling process is performed. A processor calculates, from the film thickness data, a polishing index value indicating the progress of polishing of the film.

### CROSS REFERENCE TO RELATED APPLICATION

This document claims priority to Japanese Patent Application No. 2012-94114, filed Apr. 17, 2012, the entire contents of which are hereby incorporated by reference.

### BACKGROUND OF THE INVENTION

1. Field of the Invention

The present invention relates to a polishing apparatus and a polishing method for a substrate, such as a semiconductor wafer, and more particularly to a polishing apparatus and a polishing method capable of detecting a polishing end point of the substrate.

2. Description of the Related Art

A polishing apparatus for polishing a substrate, such as a wafer, has a polishing end point detection device using an optical sensor, an eddy current sensor, or the like in order to detect a polishing end point of the substrate (for example, see Japanese laid-open patent publication No. 2004-154928 and Japanese laid-open patent publication No. 2009-99842). The optical sensor is mainly used for monitoring a progress of polishing of an insulating layer (transparent layer) and for detecting its polishing end point. The eddy current sensor is mainly used for monitoring a progress of polishing of a conductive layer (metal film) and for detecting its polishing end point.

FIG. 16 is a schematic view showing a typical polishing apparatus. The polishing apparatus includes a polishing table 101 for supporting a polishing pad 100 thereon, a top ring 110 for holding and rotating a wafer W, a slurry supplying mechanism 115 for supplying polishing liquid (slurry) onto the polishing pad 100, and a sensor head 120 for obtaining a film thickness data which varies in accordance with a film thickness of the wafer W. The sensor head 120 is the aforementioned optical sensor or eddy current sensor. This sensor 120 is disposed in the polishing table 101 and obtains the film thickness data of wafer W with each rotation of the polishing table 101.

The top ring 110 and the polishing table 101 are rotated as shown by arrows. In this state, the wafer W is pressed against a polishing surface 100a of the polishing pad 100 by the top ring 110, while the polishing liquid is supplied onto the polishing pad 100 from the slurry supplying mechanism 115. The wafer W is thus polished by a sliding contact with the polishing pad 100 in the presence of the polishing liquid. During polishing of the wafer W, the sensor head 120 is rotated together with the polishing table 101 and obtains the film thickness data while traversing a surface of the wafer W as shown by arrow A. When the film thickness has reached a predetermined target value, polishing of the wafer W is finished.

As semiconductor devices have been becoming finer in recent years, a demand for accuracy of the polishing end point detection has extremely become strict. However, the optical sensor and the eddy current sensor cannot obtain an accurate condition of the polished wafer due to a variation in the film thickness in a circumferential direction of the wafer surface and due to an influence of interconnect patterns. Therefore, it is difficult for the conventional polishing end point detection device to meet the required accuracy with respect to a residual film thickness and a polishing quantity.

FIG. 17 is a graph showing an example of a film thickness distribution in the circumferential direction of the wafer. More specifically, FIG. 17 shows the thickness distribution of copper in the circumferential direction of the wafer (0 to 360°) in an area located at a distance of 116 mm from a central point of the wafer and in an area located at a distance of 145 mm from a central point of the wafer. As shown in FIG. 17, there is a variation in the film thickness before polishing in the circumferential direction of the wafer. This variation in the film thickness in the circumferential direction could lower the accuracy of the polishing end point detection.

In order to improve such a problem, the following processes are carried out as shown in FIG. 18. The polished wafer is transferred from the polishing table to an in-line film thickness measuring device, where the film thickness of wafer is measured, and the wafer is, if needed, re-polished (reworked). However, in order to reduce scrap wafers caused by excessive polishing, it is necessary to set a polishing time to be shorter than a time required for achieving a target film thickness. As a result, there exists a problem that a production efficiency is lowered due to an increase in percentage of the rework.

In the process line shown in FIG. 18, a polishing rate is updated by measuring the film thickness after polishing (and before polishing) with use of the in-line film thickness measuring device, so that the latest polishing rate is fed back to the polishing time of subsequent wafers. However, since the polished wafer is needed to go through processes, such as a cleaning process and a drying process, before the film thickness measurement performed by the film thickness measuring device, there exists a problem that a correction of the polishing time cannot be reflected until four or five subsequent wafers are polished.

### SUMMARY OF THE INVENTION

The present invention has been made in view of the above drawbacks. It is therefore an object of the present invention to provide a polishing apparatus and a polishing method capable of accurately obtaining a condition of a polished substrate on a polishing pad even if there is a variation in film thickness in a circumferential direction of the substrate.

One aspect of the present invention for achieving the above object provides a polishing apparatus for polishing a substrate having a film formed thereon. The apparatus includes: a polishing table for supporting a polishing pad thereon; a top ring configured to press the substrate against the polishing pad while rotating the substrate; a sensor configured to obtain a film thickness data that varies in accordance with a thickness of the film, the sensor being disposed in the polishing table and being rotated together with the polishing table; and a processor configured to monitor progress of polishing of the substrate based on the film thickness data. The polishing apparatus is configured to perform an idling process while rotating the polishing table and the substrate, the idling process being a process in which polishing of the substrate on the polishing pad does not progress substantially. The sensor obtains the film thickness data while the idling process is performed. The processor calculates, from the film thickness data, a polishing index value indicating the progress of polishing of the film.

Another aspect of the present invention for achieving the above object provides a polishing method of polishing a substrate having a film formed thereon The method includes: rotating a polishing table in which a sensor is disposed; pressing the substrate against a polishing pad on the polishing table while rotating the substrate to polish the substrate; performing an idling process while rotating the polishing table and the substrate, the idling process being a process in which polishing of the substrate on the polishing pad does not progress substantially; obtaining a film thickness data, which varies in accordance with a thickness of the film, by the sensor while performing the idling process; and calculating a polishing index value indicating the progress of polishing of the film from the film thickness data.

According to the present invention, the film thickness data that varies in accordance with the thickness of the film is obtained during the idling process. In this idling process, polishing of the film does not progress substantially, i.e., the film thickness does not change substantially. Therefore, even if a measuring time increases to some degree, the accurate film thickness data can be obtained. Moreover, since a longer measuring time is allowed, the sensor can move across the substrate several times during the idling process. As a result, an influence of the variation in the film thickness in the circumferential direction of the substrate can be reduced. Further, because the film thickness data can be obtained while the substrate is placed on the polishing pad, it is possible to reflect the polishing index value on the polishing process of the substrate that is being currently polished.

### BRIEF DESCRIPTION OF THE DRAWINGS

FIG. 1 is a schematic view of a polishing apparatus according to an embodiment of the present invention;

FIG. 2A and FIG. 2B are views each showing paths of a sensor head described on a wafer surface;

FIG. 3 is a flowchart showing an embodiment of determining a polishing end point of a wafer based on a film thickness of the wafer;

FIG. 4 is a flowchart showing an embodiment of determining the polishing end point of the wafer based on an amount of the wafer polished;

FIG. 5 is a view showing an example of the polishing apparatus having an optical sensor as the sensor head;

FIG. 6 is a schematic view illustrating a principle of the optical sensor;

FIG. 7 is a plan view showing a positional relationship between the wafer and a polishing table;

FIG. 8 is a diagram showing a spectrum created by a processor;

FIG. 9 is a diagram illustrating a process of determining a current film thickness from a comparison of the created spectrum with a plurality of reference spectra;

FIG. 10 is a schematic view showing two spectra corresponding to a film thickness difference Δα;

FIG. 11 is a diagram illustrating a principle of an eddy current sensor;

FIG. 12 is a diagram showing a graph drawn by plotting coordinates X and Y, which change with a polishing time, on a XY coordinate system;

FIG. 13 shows a graph obtained by rotating the graph in FIG. 12 through 90 degrees in a counterclockwise direction and further translating the resulting graph;

FIG. 14 is a graph showing arcuate paths of the coordinates X and Y that change in accordance with a distance between a coil and a wafer;

FIG. 15 is a graph showing an angle 0 that varies in accordance with polishing time;

FIG. 16 is a schematic view showing a typical polishing apparatus;

FIG. 17 is a graph showing an example of a film thickness distribution along a circumferential direction of a wafer; and

FIG. 18 is a schematic view showing a process sequence of the wafer.

### DETAILED DESCRIPTION OF THE PREFERRED EMBODIMENTS

Embodiments of the present invention will be described below with reference to the drawings.

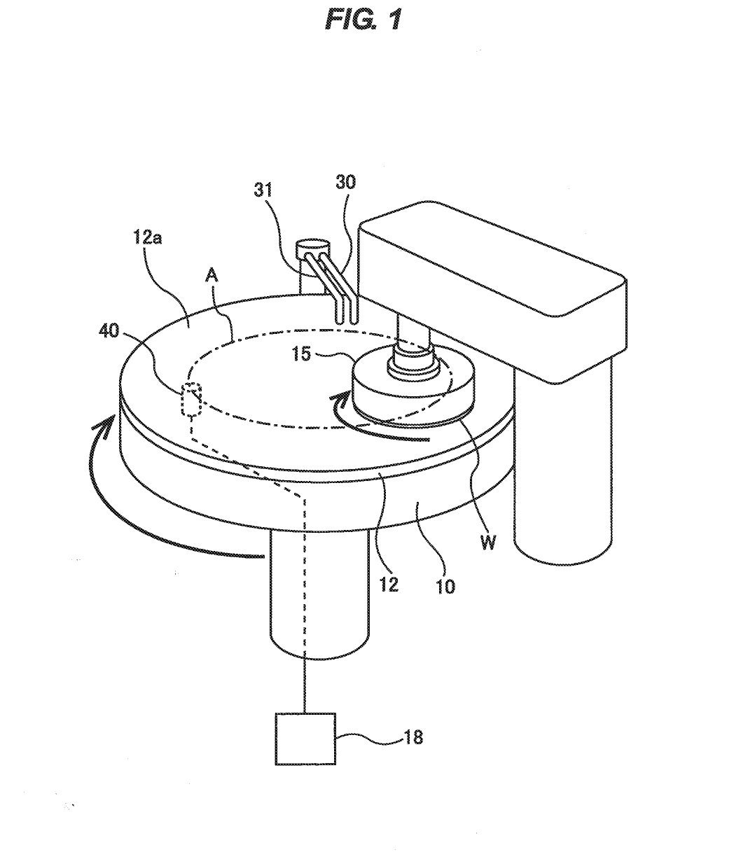

FIG. 1 is a schematic view of a polishing apparatus according to an embodiment of the present invention. As shown in FIG. 1, the polishing apparatus includes a polishing table 10 for supporting a polishing pad 12 thereon, a top ring 15 configured to hold and rotate a wafer (substrate) W, a slurry supply mechanism 30 configured to supply a polishing liquid (slurry) onto the polishing pad 12, and a sensor head (which may be referred to simply as a sensor) 40 configured to obtain film thickness data that varies in accordance with a film thickness of the wafer W. Examples of the sensor head 40 include an optical sensor and an eddy current sensor. This sensor (or sensor head) 40 is disposed in the polishing table 10. Each time the polishing table 10 makes one revolution, the sensor head 40 obtains the film thickness data in a plurality of zones including a central zone of the wafer W.

The top ring 15 is configured to hold the wafer W on its lower surface by vacuum suction. The top ring 15 and the polishing table 10 rotate as indicated by arrows. In this state, the top ring 15 presses the wafer W against a polishing surface 12a of the polishing pad 12, while the slurry supply mechanism 30 supplies the polishing liquid onto the polishing pad 12. The wafer W is thus polished by a sliding contact with the polishing pad 12 in the presence of the polishing liquid. During polishing of the wafer W, the sensor head 40 rotates together with the polishing table 10 and obtains the film thickness data while travelling across a surface of the wafer W as shown by arrow A. When the film thickness has reached a predetermined target value, polishing of the wafer W is terminated.

A water supply nozzle 31 is provided adjacent to the slurry supply mechanism 30, so that water (preferably pure water) is supplied onto the polishing pad 12 from the water supply nozzle 31. The sensor head 40 is coupled to a processor 18, and the film thickness data, obtained by the sensor head 40, is sent to the processor 18. This processor 18 is configured to monitor progress of polishing of the wafer W based on the film thickness data and detects a polishing end point of the wafer.

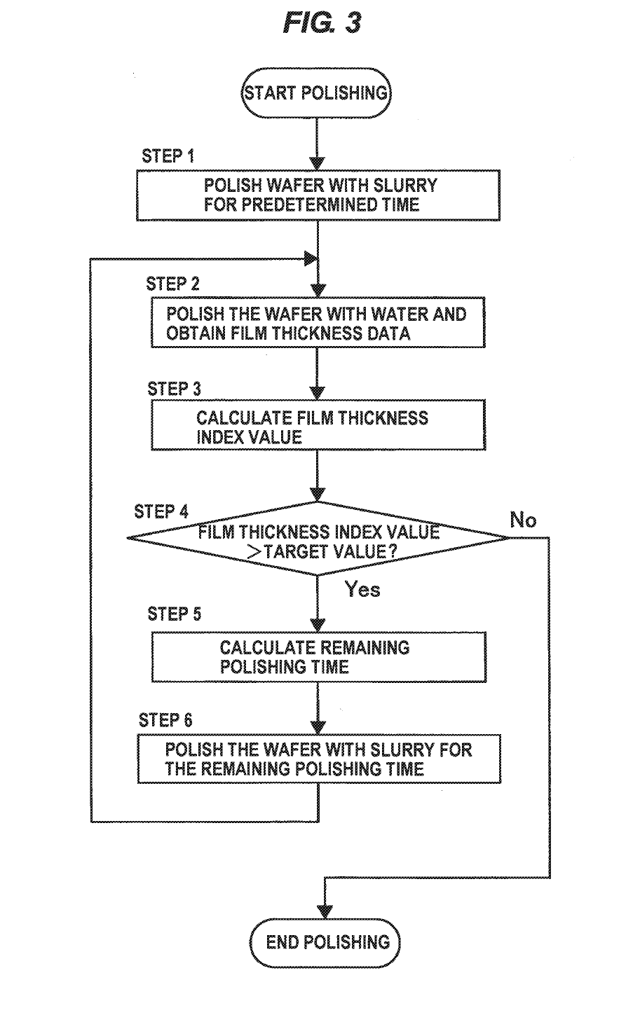

Next, an embodiment of a method of determining the polishing end point of the wafer based on the film thickness of the wafer will be described with reference to a flowchart shown in FIG. 3.

At step 1, the wafer is polished for a predetermined polishing time, while the polishing liquid (i.e., slurry) is supplied from the slurry supply mechanism 30 onto the polishing pad 12. The predetermined polishing time is preferably set to be longer so long as a target film thickness is not reached.

At step 2, instead of the slurry, the water (preferably pure water) is supplied from the water supply nozzle 31 onto the polishing pad 12. While the water is supplied onto the polishing pad 12, the wafer is water-polished for a predetermined idling time. This water-polishing is an idling process in which polishing of the wafer does not progress substantially because the slurry is not used. During this idling process, the sensor head 40 obtains the film thickness data, which is a data that varies in accordance with the thickness of the film of the wafer. For example, the film thickness data may be numerical data directly indicating the film thickness, or may be numerical data indicating relative value of the film thickness. Because the slurry does not exist between the sensor head 40 and the wafer in the idling process, the sensor head 40 can obtain more accurate film thickness data. Moreover, because the film thickness does not change during the idling process, the sensor head 40 can obtain more accurate film thickness data.

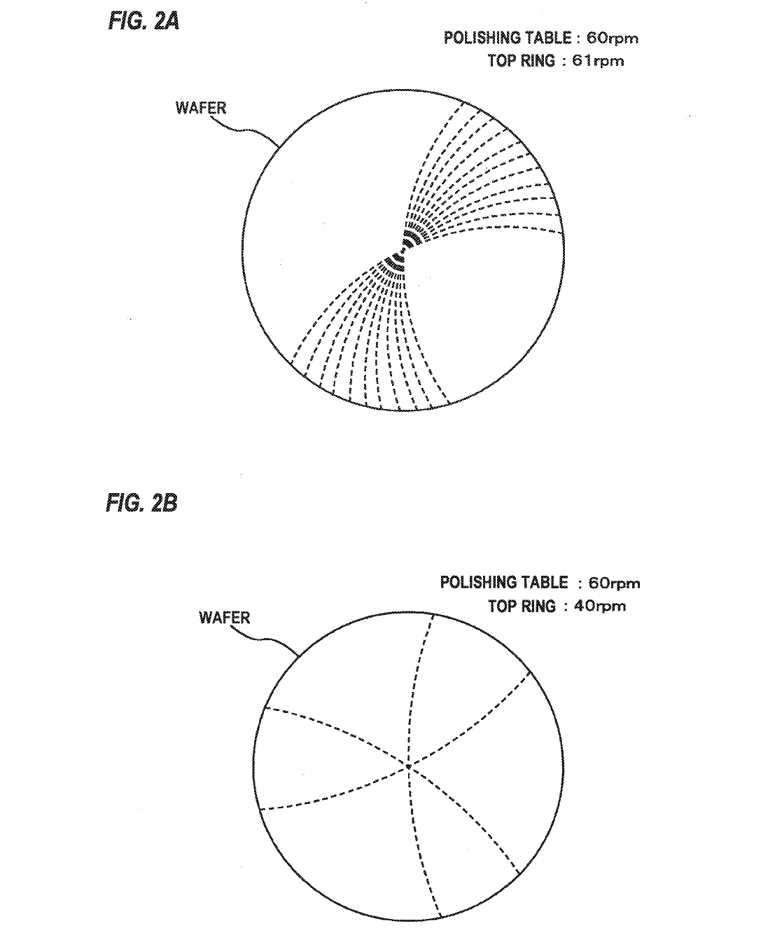

A measuring time for which the sensor head 40 obtains the film thickness data is such that multiple paths, described by the sensor head 40 on the wafer surface, are distributed evenly in a circumferential direction of the wafer. This measuring time may be longer than a time required for the multiple paths to be distributed evenly over the wafer surface. The measuring time is determined by a ratio of a rotational speed of the polishing table 10 to a rotational speed of the top ring 15 (i.e., a rotational speed of the wafer). For example, when the rotational speed of the polishing table 10 is 60 min⁻¹ and the rotational speed of the top ring 15 is 61 min⁻¹, the sensor head 40 describes its paths on the wafer surface as shown in FIG. 2A. A time required for these paths to be distributed evenly in the circumferential direction of the wafer is 60 seconds. Therefore, the idling process is performed for at least 60 seconds, and the film thickness data is obtained by the sensor head 40 during the idling process.

However, if the measuring time is set to 60 seconds, a polishing process as a whole increases. Thus, in order to shorten the measuring time, it is preferable to change the ratio of the rotational speed of the polishing table 10 to the rotational speed of the top ring 15 in the idling process. For example, when the rotational speed of the polishing table 10 is 60 min⁻¹ and the rotational speed of the top ring 15 is 40 min⁻¹, the sensor head 40 describes its paths on the wafer surface as shown in FIG. 2B. In this case, a time required for these paths to be distributed evenly in the circumferential direction of the wafer is 3 seconds.

Generally, if the ratio of the rotational speed of the polishing table 10 to the rotational speed of the top ring 15 is changed greatly during polishing of the wafer, a polishing profile of the wafer could be affected adversely. In the idling process, polishing of the wafer does not progress substantially. Therefore, the polishing profile is not affected even if the ratio of the rotational speed of the polishing table 10 to the rotational speed of the top ring 15 is changed. Accordingly, it is possible to greatly change the ratio of the rotational speed of the polishing table 10 to the rotational speed of the top ring 15 in the idling process.

At an initial stage of the water-polishing process, the slurry may remain between the wafer and the sensor head 40 and polishing of the wafer may progress. Therefore, the idling time is preferably a time given by adding a predetermined additional time to the above-described measuring time. Further, it is preferable not to obtain the film thickness data at the initial stage of the idling process. In addition, at the initial stage of the idling process, the top ring 15 may be elevated with the wafer attracted thereto so that the polishing table 10 is allowed to rotate at a higher speed (e.g., 150 min⁻¹) so as to expel the slurry quickly from the polishing pad 12 on the polishing table 10 via a centrifugal force.

The idling process is a process in which polishing of the wafer does not progress substantially. More specifically, the progress of wafer polishing during the idling process is preferably at most one fifth of a required precision (permissible error) of the film thickness or an amount of the film removed by polishing. For example, when the required precision is ±5 nm, the amount of the film removed by polishing during the idling process is at most 1 nm. The idling process is not limited to the water-polishing process so long as polishing of the wafer does not progress substantially. For example, the idling process may be a process in which the top ring 15 attracts the wafer by the vacuum suction or the like so that the polishing pad 12 exerts substantially no load on the wafer.

At step 3, the processor 18 calculates a film thickness average data which is an average data of the film thickness data obtained during the idling process, and determines a film thickness index value, which corresponds to an average film thickness over the wafer surface in its entirety, from the film thickness average data. This film thickness index value is an index value indicating the film thickness, and is therefore a polishing index value representing the progress of polishing of the film. For example, the film thickness index value may be a value directly representing the film thickness, a value indirectly representing the film thickness, or an estimated film thickness value determined from a comparison of the film thickness data with reference data. Since the film thickness index value is determined from the average data of the film thickness data obtained during the idling process, this index value represents an average resulting from evening out of the variation in the film thickness in the circumferential direction of the wafer. Therefore, the processor 18 can obtain the film thickness index value reflecting the film thickness over the wafer surface in its entirety.

At step 4, the processor 18 compares the film thickness index value, obtained at the step 3, with a predetermined target value. The processor 18 judges that a point of time when the film thickness index value is lowered to reach the predetermined target value is a polishing end point, and terminates polishing of the wafer. The predetermined target value is a value given by adding a predetermined threshold value to a predetermined target film thickness (index value). This predetermined threshold value may be zero.

If the film thickness index value is larger than the predetermined target value as a result of the comparison between the film thickness index value and the predetermined target value, the processor 18 calculates an additional polishing time that is required for reaching the target value from a difference between the film thickness index value and the predetermined target value and a polishing rate (a removal rate of the film) obtained from previous polishing data (step 5). Then, at step 6, the wafer is polished with use of the slurry for the additional polishing time. If two or more idling processes have been performed during polishing of the current wafer, the processor 18 calculates a latest polishing rate from the film thickness index values obtained in these idling processes and a polishing time between these idling processes. Use of the latest polishing rate enables the processor 18 to calculate a more accurate additional polishing time. After polishing of the wafer in the step 6, the processing flow goes back to the water-polishing process of the step 2.

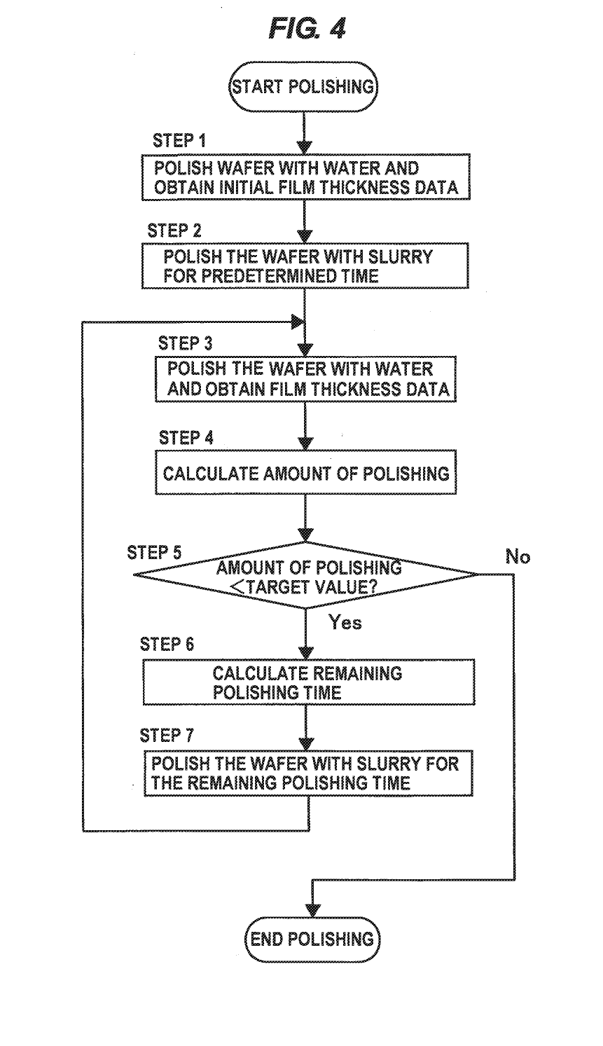

While the flowchart in FIG. 3 shows a method of determining the polishing end point based on the film thickness, it is also possible to determine the polishing end point based on an amount of the film removed by polishing of the wafer (which will be hereinafter referred to as an amount of polishing). FIG. 4 is a flowchart showing a method of determining the polishing end point based on the amount of polishing. Processes which are not described particularly in this flowchart are identical to those in the corresponding steps shown in FIG. 3 and repetitive descriptions thereof will be omitted.

At step 1, the wafer is water-polished for a predetermined idling time, while the water (preferably pure water) is supplied from the water supply nozzle 31 onto the polishing pad 12. This water-polishing is the idling process in which polishing of the wafer does not progress substantially. During the idling process, the sensor head 40 obtains an initial film thickness data. The processor 18 calculates an initial film thickness average data which is an average data of the initial film thickness data.

At step 2, the wafer is polished for a predetermined polishing time, while the polishing liquid (i.e., slurry) is supplied onto the polishing pad 12. At step 3, the water polishing process (i.e., the idling process) is performed again, while the sensor head 40 obtains the film thickness data with respect to the polished wafer. At step 4, the processor 18 calculates a current film thickness average data which is an average data of the film thickness data obtained at the step 3. Further, the processor 18 calculates an absolute value of a difference between the initial film thickness average data and the current film thickness average data. This absolute value of the difference represents the amount of the film that has been removed as a result of the slurry polishing process of the step 2 performed between the two idling processes, i.e., the amount of polishing. If three or more idling processes are performed, the absolute value of the difference obtained between the latest two idling processes is accumulated to update the amount of polishing. The amount of polishing determined in this manner is the polishing index value representing the progress of polishing of the film.

At step 5, the processor 18 compares the amount of polishing, obtained at the step 4, with a predetermined target value. The processor 18 judges that a point of time when the amount of polishing is increased to reach the predetermined target value is a polishing end point, and terminates polishing of the wafer. The predetermined target value is a value given by subtracting a predetermined threshold value from a predetermined target amount of polishing. This predetermined threshold value may be zero.

If the amount of polishing is smaller than the predetermined target value as a result of the comparison between the amount of polishing and the predetermined target value, the processor 18 calculates an additional polishing time that is required for reaching the target value from a polishing rate and a difference between the amount of polishing and the predetermined target value (step 6). This polishing rate can be calculated from the amount of polishing and a corresponding polishing time. Then, at step 7, the wafer is polished with use of the slurry for the additional polishing time. After polishing of the wafer in the step 7, the processing flow goes back to the step 3.

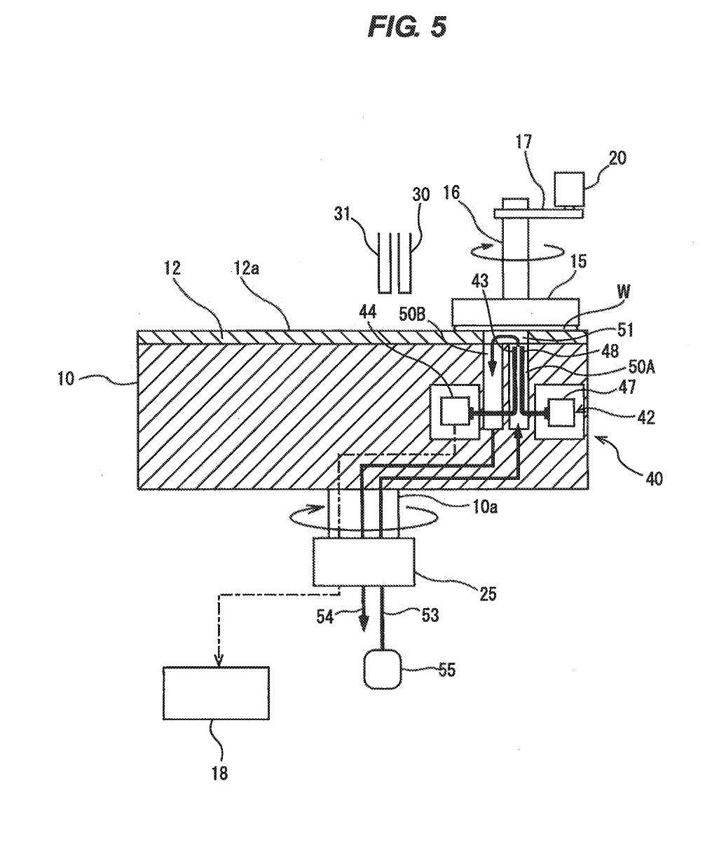

Next, a specific example of the polishing apparatus according to an embodiment of the present invention will be described. FIG. 5 is a view showing an example of the polishing apparatus having an optical sensor as the sensor head 40. As shown in FIG. 5, the polishing apparatus includes the polishing table 10, the top ring 15 supported by a top ring shaft 16, and the processor 18 configured to detect the polishing end point of the wafer W based on the several kinds of data. The top ring 15 is configured to be able to hold the wafer W on its lower surface. The top ring shaft 16 is coupled to a top ring motor 20 through a coupling device 17, such as belt, so that the top ring shaft 16 is rotated by the top ring motor 20. This rotation of the top ring shaft 16 causes the top ring 15 to rotate in a direction as indicated by arrow.

The polishing table 10 is coupled to a table motor 25 through a table shaft 10a, so that the polishing table 10 is rotated by the table motor 25 in a direction indicated by arrow. This table motor 25 is provided below the polishing table 10 The polishing pad 12 is secured to an upper surface of the polishing table 10. The polishing pad 12 has an upper surface 12a, which provides a polishing surface for polishing the wafer W.

The top ring shaft 16 is elevated and lowered by an elevating mechanism (not shown in the drawing). The top ring 15, holding the wafer on its surface, is lowered by the top ring shaft 16 and presses the wafer W against the upper surface (i.e., the polishing surface) 12a of the polishing pad 12. During polishing of the wafer W, the top ring 15 and the polishing table 10 are rotated, while the polishing liquid (i.e., the slurry) is supplied onto the polishing pad 12 from the slurry supply nozzle 30 arranged above the polishing table 10. The surface of the wafer W is polished by a mechanical action of abrasive grains contained in the polishing liquid and a chemical action of the polishing liquid.

The sensor head 40 is the optical sensor configured to irradiate the wafer surface with light, receive the light reflected from the wafer, and break up the reflected light according to wavelength. This sensor head 40 is disposed in the polishing table 10 and is rotated together with the polishing table 10. The sensor head 40 irradiates the surface of the wafer W with the light, receives the reflected light from the wafer W, and measures intensity of the reflected light at each wavelength. The sensor head 40 includes an irradiator 42 for irradiating the surface, to be polished, of the wafer W with the light, an optical fiber 43 as an optical receiver for receiving the reflected light from the wafer W, a spectrometer 44 configured to resolve the reflected light according to the wavelength and measure the intensity of the reflected light over a predetermined wavelength range.

The polishing table 10 has a first hole 50A and a second hole 50B having upper open ends lying in the upper surface of the polishing table 10. The polishing pad 12 has a through-hole 51 at a position corresponding to the holes 50A and 50B. The holes 50A and 50B are in fluid communication with the through-hole 51, which has an upper open end lying in the polishing surface 12a. The first hole 50A is coupled to a liquid supply source 55 via a liquid supply passage 53 and a rotary joint (not shown). The second hole 50B is coupled to a liquid discharge passage 54.

The irradiator 42 includes a light source 47 for emitting multiwavelength light and the optical fiber 48 coupled to the light source 47. The optical fiber 48 is an optical transmission element for directing the light, emitted by the light source 47, to the surface of the wafer W. The tip ends of the optical fiber 48 and the optical fiber 43 lie in the first hole 50A and are located near the surface, to be polished, of the wafer W. The tip ends of the optical fiber 48 and the optical fiber 43 are arranged so as to face the wafer W held by the top ring 15, so that multiple zones of the wafer W are irradiated with the light each time the polishing table 10 makes one revolution. Preferably, the tip ends of the optical fiber 48 and the optical fiber 43 are arranged so as to face the center of the wafer W held by the top ring 15.

During polishing of the wafer W, the liquid supply source 55 supplies water (preferably pure water) as a transparent liquid into the first hole 50A through the liquid supply passage 53. The water fills a space formed between the lower surface of the wafer W and the tip ends of the optical fibers 48 and 43. The water further flows into the second hole 50B and is expelled therefrom through the liquid discharge passage 54. The polishing liquid is discharged together with the water and thus a path of light is secured. The liquid supply passage 53 is provided with a valve (not shown in the drawing) configured to operate in conjunction with the rotation of the polishing table 10. The valve operates so as to stop the flow of the water or reduce the flow of the water when the wafer W is not located over the through-hole 51.

The optical fiber 48 and the optical fiber 43 are arranged in parallel with each other. The tip ends of the optical fiber 48 and the optical fiber 43 are substantially perpendicular to the surface of the wafer W, so that the optical fiber 48 directs the light to the surface of the wafer W substantially perpendicularly.

During polishing of the wafer W, the irradiator 42 irradiates the wafer W with the light, and the optical fiber (optical receiver) 43 receives the light reflected from the wafer W. The spectrometer 44 measures the intensity of the reflected light at each wavelength over the predetermined wavelength range and sends light intensity data to the processor 18. This light intensity data is the film thickness data reflecting the film thickness of the wafer W. The processor 18 produces a spectrum showing the light intensities at the respective wavelengths from the light intensity data, and further produces the film thickness index value representing the film thickness of the wafer W from the spectrum.

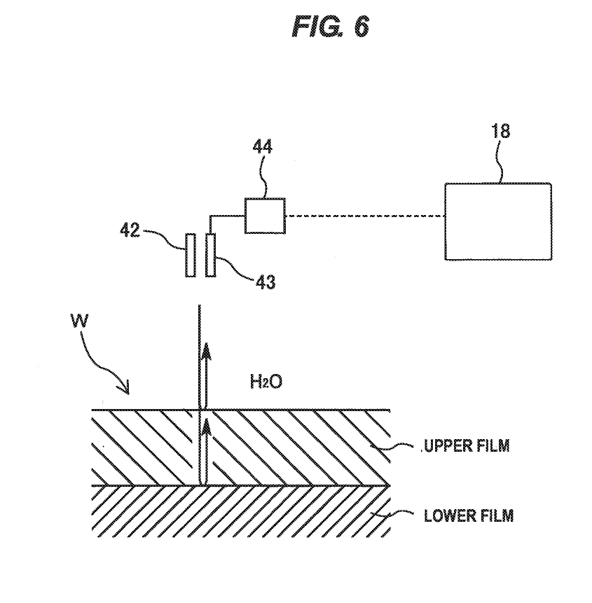

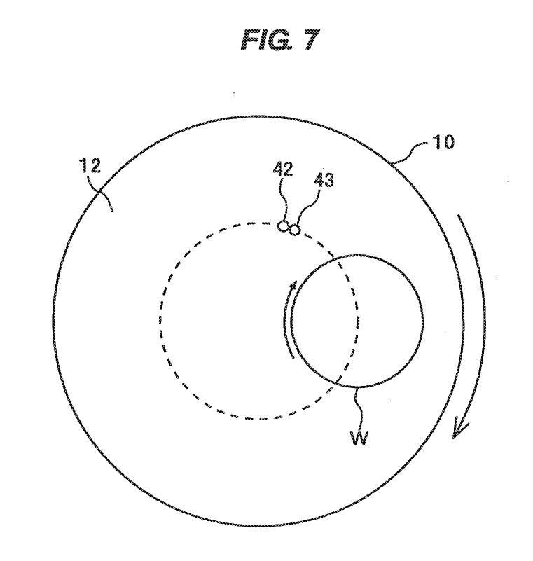

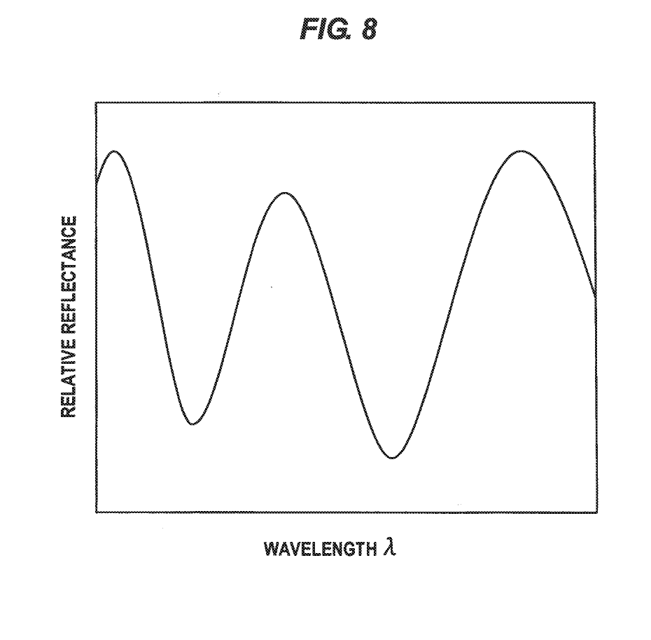

FIG. 6 is a schematic view illustrating the principle of the optical sensor, and FIG. 7 is a plan view showing a positional relationship between the wafer and the polishing table 10. In this example shown in FIG. 6, the wafer W has a lower film and an upper film formed on the lower film. The irradiator 42 and the optical receiver 43 are oriented toward the surface of the wafer W. The irradiator 42 is configured to direct the light to the multiple zones, including the center of the wafer W, on the surface of the wafer W each time the polishing table 10 makes one revolution.

The light, directed to the wafer W, is reflected off an interface between a medium (e.g., water in the example of FIG. 6) and the upper film and an interface between the upper film and the lower film. Light waves from these interfaces interfere with each other. The manner of interference between the light waves varies according to the thickness of the upper film (i.e., a length of an optical path). As a result, the spectrum, produced from the reflected light from the wafer, varies according to the thickness of the upper film. The spectrometer 44 breaks up the reflected light according to the wavelength and measures the intensity of the reflected light at each wavelength. The processor 18 produces the spectrum from the light intensity data obtained from the spectrometer 44. This spectrum is expressed as a line graph (i.e., a spectral waveform) indicating a relationship between the wavelength and the intensity of the light. The intensity of the light can also be expressed as a relative value, such as a reflectance or a relative reflectance.

FIG. 8 is a diagram showing the spectrum created by the processor 18. In FIG. 8, horizontal axis represents the wavelength of the reflected light, and vertical axis represents relative reflectance derived from the intensity of the light. The relative reflectance is an index that represents the intensity of the reflected light. More specifically, the relative reflectance is a ratio of the intensity of the reflected light to a predetermined reference intensity. By dividing the intensity of the light (i.e., the actually measured intensity) at each wavelength by the corresponding reference intensity, unwanted noise, such as a variation in the intensity inherent in an optical system or the light source, are removed from the actually measured intensity. As a result, the spectrum reflecting only the thickness information of the upper film can be obtained.

The predetermined reference intensity may be an intensity of the reflected light obtained when a silicon wafer (bare wafer) with no film thereon is being polished in the presence of water. In the actual polishing process, the relative reflectance is obtained as follows. A dark level (which is a background intensity obtained under the condition that the light is cut off) is subtracted from the actually measured intensity to determine a corrected actually measured intensity. Further, the dark level is subtracted from the reference intensity to determine a corrected reference intensity. Then the relative reflectance is calculated by dividing the corrected actually measured intensity by the corrected reference intensity. That is, the relative reflectance R(λ) can be calculated by using the following equation (1).

$$R ( λ ) = \frac{E ( λ ) - D ( λ )}{B ( λ ) - D ( λ )} \qquad ( 1 )$$

where λ is wavelength, E(λ) is the intensity of the reflected light at the wavelength λ, B(λ) is the reference intensity at the wavelength λ, and D(λ) is the dark level at the wavelength λ (i.e., the intensity of the light obtained under the condition that the light is cut off).

The processor 18 calculates the average data from the film thickness data (i.e., the light intensity data) obtained during the idling process, and produces the spectrum from the average data. Further, the processor 18 compares the spectrum with a plurality of reference spectra so as to determine a reference spectrum that is most similar to the spectrum produced. A film thickness associated with the determined reference spectrum is determined to be a current film thickness by the processor 18. The plurality of reference spectra are those obtained in advance by polishing a wafer of the same type as the wafer to be polished. Each reference spectrum is associated with a film thickness at a point of time when that reference spectrum is obtained. Specifically, each reference spectrum is obtained at different film thickness, and the plurality of reference spectra correspond to different film thicknesses. Therefore, the current film thickness can be estimated by determining the reference spectrum that is most similar to the current spectrum. This estimated film thickness is the above-mentioned film thickness index value.

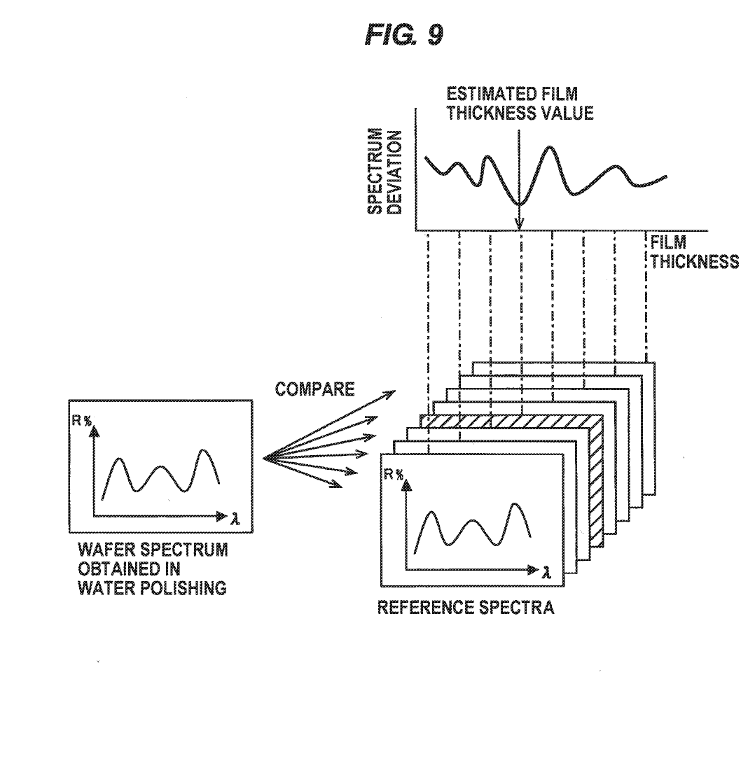

FIG. 9 is a diagram illustrating a process of determining the current film thickness from the comparison of the current spectrum created by the processor 18 with the plurality of reference spectra. As shown in FIG. 9, the processor 18 compares the current spectrum, which is produced from the light intensity data, with the plurality of reference spectra, and determines the most similar reference spectrum. More specifically, the processor 18 calculates a deviation between the current spectrum and each reference spectrum, and specifies the reference spectrum with the smallest deviation as the most similar reference spectrum. The processor 18 determines that the current film thickness is the film thickness associated with the most similar reference spectrum specified.

The processor 18 determines the polishing end point according to the flowchart shown in FIG. 3 or FIG. 4. In the case of the flowchart shown in FIG. 3, the estimated film thickness is used as the film thickness index value. In the case of the flowchart shown in FIG. 4, the initial film thickness is determined from the initial film thickness data (i.e., initial light intensity data) in accordance with the above-described method. The amount of polishing can be determined by subtracting the current estimated film thickness value from the initial film thickness.

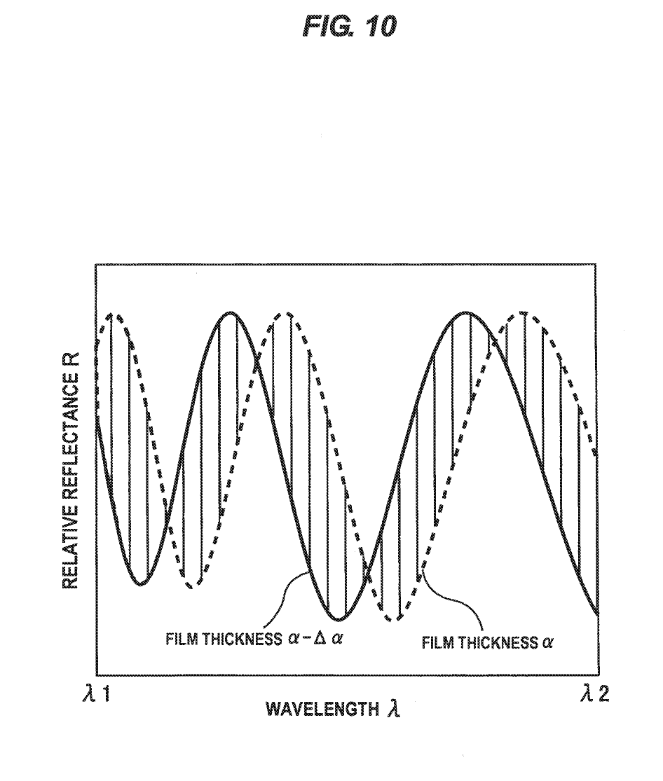

The amount of polishing shown in FIG. 4 may be determined from an amount of change in the spectrum that varies in accordance with the film thickness. FIG. 10 is a schematic view showing two spectra corresponding to a film thickness difference Δα. In FIG. 10, α represents the film thickness. This film thickness α decreases with time during polishing of the wafer (Δα>0). As shown in FIG. 10, as the film thickness changes, the spectrum moves along a wavelength axis. The amount of change between the two spectra obtained in the two idling processes corresponds to a region (indicated by hatching) surrounded by these spectra. An area of this region corresponds to the absolute value of the difference in the film thickness data between the two idling processes. Therefore, the amount of polishing can be determined by calculating the area of this region. The amount of polishing D can be determined using the following equation (2).

$$D = {\sum }_{λ 1}^{λ 2} \vert Rc ( λ ) - Rp ( λ ) \vert \qquad ( 2 )$$

where λ is wavelength of the light, λ1, λ2 are minimum wavelength and maximum wavelength that determine the wavelength range of the spectrum to be monitored, Rc is the relative reflectance obtained in the latest idling process, and Rp is the relative reflectance obtained in the previous idling process. If three or more idling processes are performed, the amount of polishing between the latest two idling processes is accumulated to update the amount of polishing D.

Instead of the relative reflectance R(λ), normalized relative reflectance R_{N}(λ) may be used in the equation (2). This normalized relative reflectance R_{N}(λ) is given by dividing the relative reflectance R(λ) by an average of the relative reflectance in a predetermined wavelength range [λ1, λ2]. Use of such normalized relative reflectance can cancel a change in quantity of the light that might be caused by wear of the polishing pad 12.

In case arrangements of optical elements in the spectrometer 44 (e.g., slit, diffraction grating, detector, and the like) are changed, the wavelength of the spectrum may be shifted. Such a shift in the wavelength may prevent precise measurement of the film thickness. Therefore, it is preferable to correct the wavelength in accordance with the following wavelength correction method, which includes the steps of irradiating a surface of a reference substrate (reference wafer) with the light and receiving the light reflected from the reference substrate; breaking up the reflected light according to the wavelength to produce a reference spectrum; irradiating the surface of the reference substrate with the light and receiving the light reflected from the reference substrate; breaking up the reflected light according to the wavelength to produce a current spectrum; and creating a formula for correcting the wavelength such that the current spectrum coincides with the reference spectrum. The above-mentioned reference substrate is a substrate having a film with a uniform thickness.

The above-mentioned reference spectrum is produced by: performing a first water polishing process of polishing the reference substrate by bringing the reference substrate into sliding contact with the polishing pad 12 while supplying the water onto the polishing pad 12; irradiating the surface of the reference substrate with the light and receiving the reflected light from the reference substrate during the first water polishing process; and breaking up the reflected light according to the wavelength. The abovementioned current spectrum is produced by: performing a second water polishing process of polishing the reference substrate by bringing the reference substrate into sliding contact with the polishing pad 12 while supplying the water onto the polishing pad 12; irradiating the surface of the reference substrate with the light and receiving the reflected light from the reference substrate during the second water polishing process; and breaking up the reflected light according to the wavelength. The above-mentioned correction formula is a formula for correcting the wavelength such that a local maximum point and a local minimum point of the current spectrum coincide with a corresponding local maximum point and a corresponding local minimum point of the reference spectrum.

While the optical sensor is used as the sensor head 40 in the above-described embodiment, it is also possible to use an eddy current sensor as the sensor head 40. For example, the eddy current sensor disclosed in Japanese laid-open patent publication No. 2009-99842 can be used as the sensor head 40.

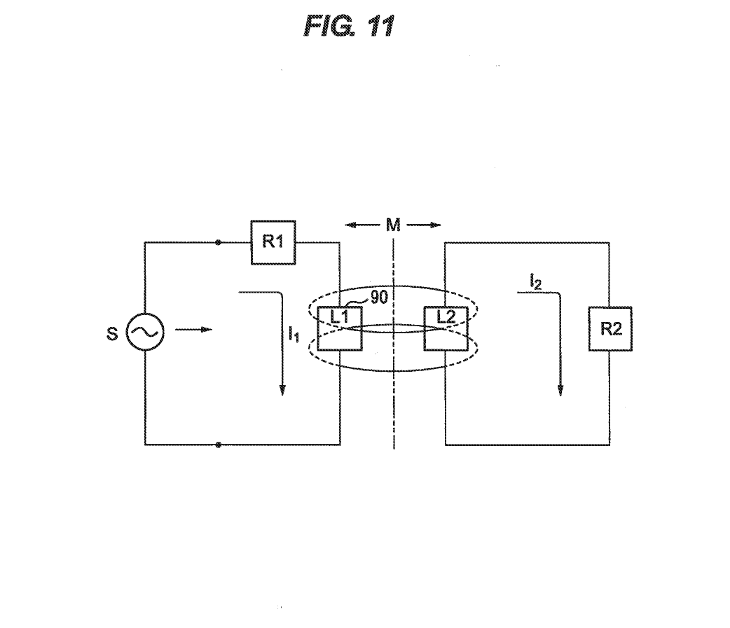

The eddy current sensor is configured to pass a high-frequency alternating current to a coil so as to induce the eddy current in a conductive film and detect the thickness of the conductive film from the change in the impedance due to a magnetic field produced by the induced eddy current. FIG. 11 is a diagram showing a circuit for illustrating the principle of the eddy current sensor. When an AC power supply S (a voltage E [V]) passes a high-frequency alternating current I₁ to a coil 90, magnetic lines of force, induced in the coil 90, pass through the conductive film. As a result, mutual inductance occurs between a sensor-side circuit and a conductive-film-side circuit, and an eddy current I₂ flows in the conductive film. This eddy current I₂ generates magnetic lines of force, which cause a change in an impedance of the sensor-side circuit. The eddy current sensor measures the thickness of the conductive film from the change in the impedance of the sensor-side circuit.

In the sensor-side circuit and the conductive-film-side circuit in FIG. 11, the following equations hold.

R₁I₁+L₁dI₁/dt+MdI₂/dt=E (3)

R₂I₂+L₂dI₂/dt+MdI₁/dt=0 (4)

where M represents mutual inductance, R₁ represents equivalent resistance of the sensor-side circuit including the coil Q, L₁ represents self-inductance of the sensor-side circuit including the coil Q, R₂ represents equivalent resistance of the conductive film in which the eddy current is induced, and L₂ represents self-inductance of the conductive film through which the eddy current flows.

Letting Iₙ=Aₙe^{j ω t} (sine wave), the above equations (3) and (4) are expressed as follows.

(R₁+jωL₁)I₁+jωMI₂=E (5)

(R₂+jωL₂)I₂+jωMI₂=0 (6)

From these equations (5) and (6), the following equations are derived.

$$\begin{matrix}{I}_{1} = E ( {R}_{2} + j ω {L}_{2} ) / [ ( {R}_{1} + j ω {L}_{1} ) ( {R}_{2} + j ω {L}_{2} ) + {ω}^{2} {M}^{2} ] \\ = E / [ ( {R}_{1} + j ω {L}_{1} ) + {ω}^{2} {M}^{2} / ( {R}_{2} + j ω {L}_{2} ) ]\end{matrix} \qquad ( 7 )$$

Thus, the impedance Φ of the sensor-side circuit is given by the following equation.

$$\begin{matrix}Φ = E / {I}_{1} \\ = [ {R}_{1} + {ω}^{2} {M}^{2} {R}_{2} / ( {R}_{2}^{2} + {ω}^{2} {L}_{2}^{2} ) ] + \\ j ω [ {L}_{1} - {ω}^{2} {L}_{2} {M}^{2} / ( {R}_{2}^{2} + {ω}^{2} {L}_{2}^{2} ) ]\end{matrix} \qquad ( 8 )$$

Substituting X and Y for a real part (i.e., a resistance component) and an imaginary part (i.e., an inductive reactance component) respectively, the above equation (8) is expressed as follows.

Φ=X+jωY (9)

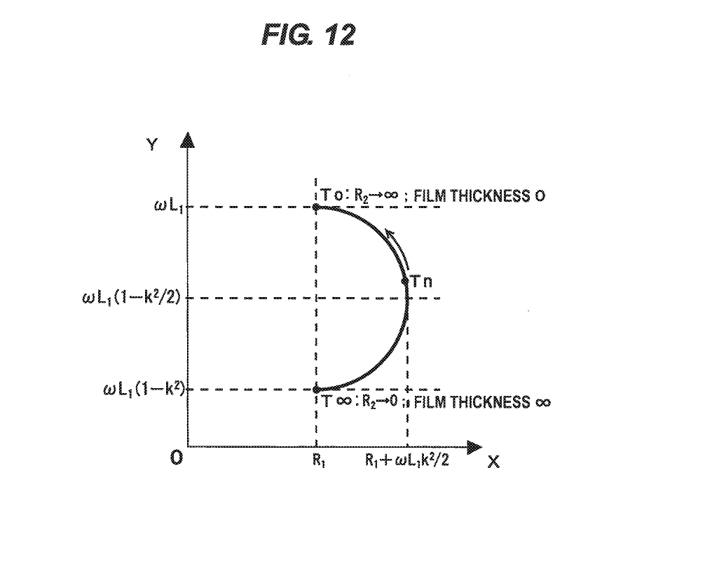

The eddy current sensor outputs the resistance component X and the inductive reactance component Y of the impedance of the electric circuit including the coil 90 of the eddy current sensor. FIG. 12 is a diagram showing a graph drawn by plotting X and Y, which change with the polishing time, on a XY coordinate system. Coordinates of a point T∞ are values of X and Y when the film thickness is infinity, i.e., R₂ is zero. Where electrical conductivity of a substrate can be neglected, coordinates of a point T0 are values of X and Y when the film thickness is zero, i.e., R₂ is infinity. A point Tn, specified by the values of X and Y, moves in a circular arc toward the point T0 as the film thickness decreases. A symbol k in FIG. 12 represents coupling coefficient, and the following relationship holds.

M=k(L₁L₂)^{1/2} (10)

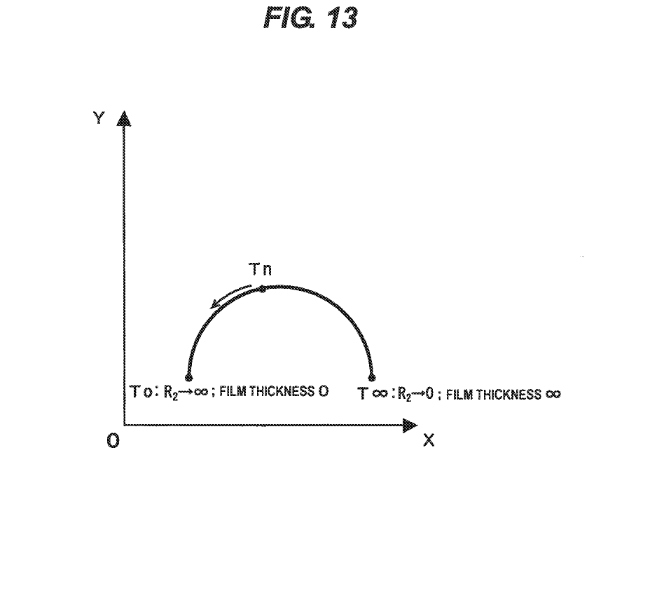

FIG. 13 shows a graph obtained by rotating the graph in FIG. 12 through 90 degrees in a counterclockwise direction and further translating the resulting graph. As shown in FIG. 13, the point Tn, which is specified by the values of X and Y, travels in a circular arc toward the point T0 as the film thickness decreases.

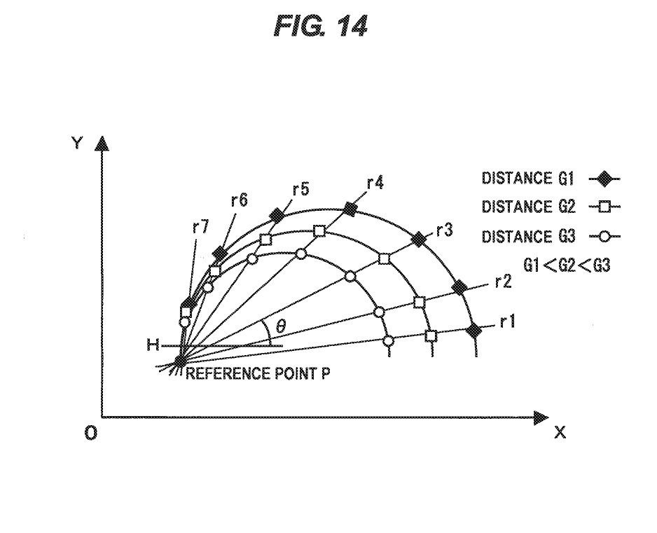

A distance between the coil 90 and the wafer W changes in accordance with a thickness of the polishing pad 12 that exists between the coil 90 and the wafer W. As a result, as shown in FIG. 14, the arcuate path of the coordinates X, Y changes in accordance with the distance G (G1 to G3) corresponding to the thickness of the polishing pad 12. As shown in FIG. 14, when points specified by the components X and Y at the same film thickness of the conductive film are connected by lines (which will be referred to as preliminary measurement lines) with different distances G between the sensor coil 90 and the wafer W, these preliminary measurement lines (r₁, r₂, r₃, . . . ) intersect each other at an intersection (a reference point) P. Each of these preliminary measurement lines rn (n=1, 2, 3 . . . ) is inclined at an elevation angle (included angle) θ with respect to a predetermined reference line (e.g., a horizontal line H in FIG. 14). This elevation angle θ varies depending on the film thickness of the conductive film. Therefore, the angle θ is the film thickness index value indicating the film thickness of the wafer W.

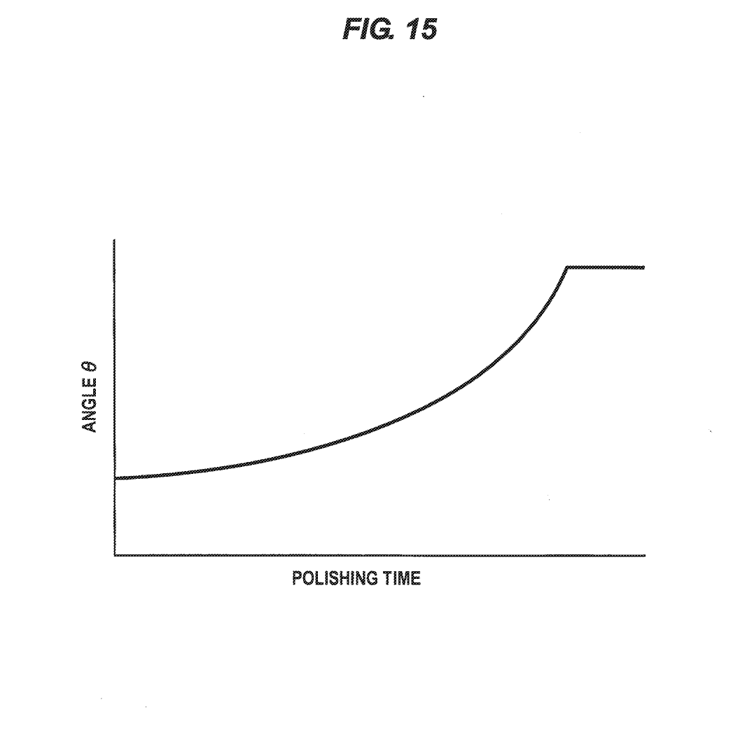

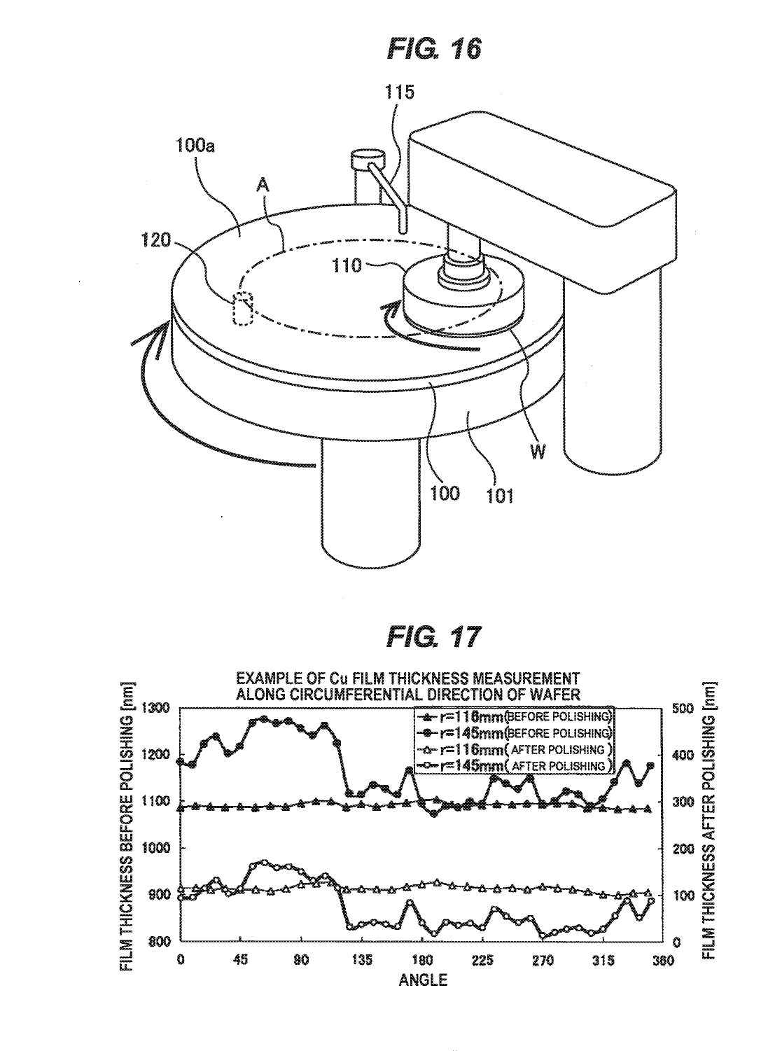

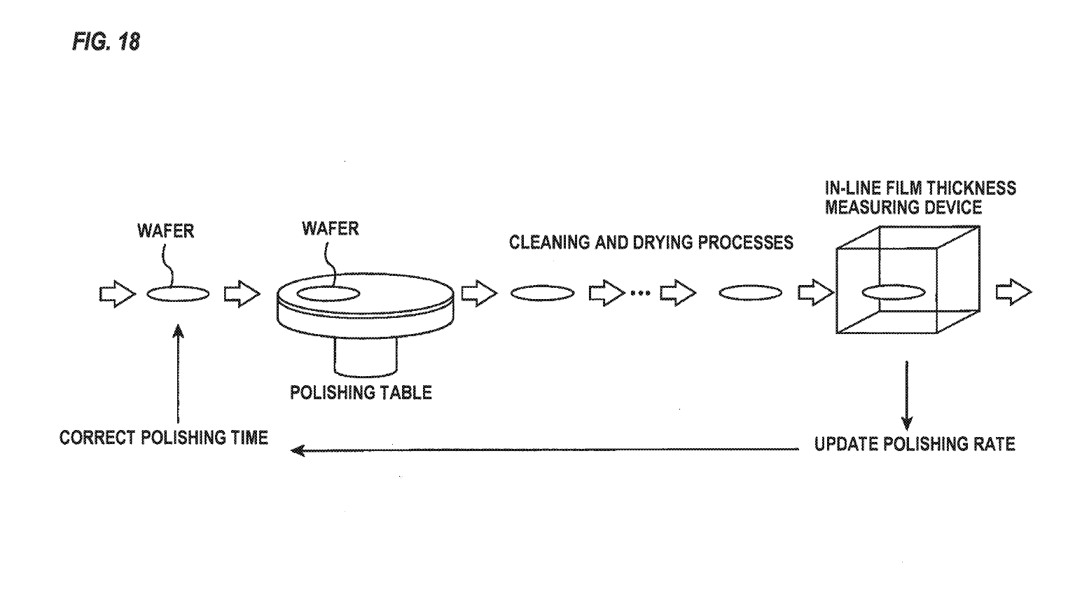

During polishing of the wafer W, the processor 18 can determine the film thickness from the angle θ with reference to correlation data showing a relationship between the angle θ and the film thickness. This correlation data is obtained in advance by polishing the same type of wafer as the wafer W to be polished and measuring the film thickness corresponding to each angle θ. FIG. 15 is a graph showing the angle θ that varies with the polishing time. Vertical axis represents the angle θ, and horizontal axis represents the polishing time. As shown in this graph, the angle θ increases with the polishing time, and becomes constant at a certain point of time. The processor 18 calculates the angle θ during polishing and determines the current film thickness from the angle θ.

While the above-described polishing apparatus has one polishing table, the present invention can be applied to a polishing apparatus having two or more polishing tables. Typically, the polishing apparatus has multiple polishing tables. This type of polishing apparatus can optimize a throughput as a whole by distributing the steps of the polishing process to the multiple polishing tables. For example, the step 1 in FIG. 3 and the steps 1 and 2 in FIG. 4 may be performed in one polishing table, and the remaining steps may be performed in other polishing table. Typically, the slurry polishing time is expected to be longer than the water-polishing time and the additional polishing time in the subsequent steps. In this case, distributing the steps of the polishing process to two polishing tables can even up the processing times between the polishing tables and can therefore realize a good throughput.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims and equivalents.

What is claimed is:

1. A polishing apparatus for polishing a substrate having a film formed thereon, said apparatus comprising:
a polishing table for supporting a polishing pad thereon;
a top ring configured to press the substrate against the polishing pad while rotating the substrate;
a sensor configured to obtain a film thickness data that varies in accordance with a thickness of the film, said sensor being disposed in said polishing table and being rotated together with said polishing table; and
a processor configured to monitor progress of polishing of the substrate based on the film thickness data,
wherein said polishing apparatus is configured to perform an idling process while rotating said polishing table and the substrate, the idling process being a process in which polishing of the substrate on the polishing pad does not progress substantially,
wherein said sensor obtains the film thickness data while the idling process is performed, and
wherein said processor calculates, from the film thickness data, a polishing index value indicating the progress of polishing of the film.

2. The polishing apparatus according to claim 1, further comprising:
a water supply nozzle configured to supply water onto the polishing pad,
wherein the idling process is a process of water-polishing the substrate while supplying the water onto the polishing pad from said water supply nozzle.

3. The polishing apparatus according to claim 1, wherein a time for which said sensor obtains the film thickness data in the idling process is equal to or longer than a time required for paths of said sensor described on the substrate to be distributed evenly in a circumferential direction of the substrate.

4. The polishing apparatus according to claim 3, wherein at least one of a rotational speed of said polishing table and a rotational speed of the substrate is changed in the idling process.

5. The polishing apparatus according to claim 1, wherein said processor is configured to calculate an average data of the film thickness data obtained in the idling process and determine the polishing index value from the average data.

6. The polishing apparatus according to claim 1, wherein said processor is configured to determine a polishing end point of the substrate based on the polishing index value.

7. The polishing apparatus according to claim 6, wherein said processor is configured to calculate an additional polishing time required for the polishing index value to reach a predetermined target value.

8. The polishing apparatus according to claim 1, wherein the polishing index value is a film thickness index value indicating the thickness of the film.

9. The polishing apparatus according to claim 1, wherein the polishing index value is an amount of polishing which represents an amount of the film removed by polishing of the substrate.

10. The polishing apparatus according to claim 9, wherein said processor is configured to determine the amount of polishing by calculating an absolute value of a difference between two film thickness data obtained in the idling process and a previous idling process.

11. The polishing apparatus according to claim 1, wherein said sensor is an optical sensor.

12. The polishing apparatus according to claim 1, wherein said sensor is an eddy current sensor.

13. A polishing method of polishing a substrate having a film formed thereon, said method comprising:
rotating a polishing table in which a sensor is disposed;
pressing the substrate against a polishing pad on the polishing table while rotating the substrate to polish the substrate;
performing an idling process while rotating the polishing table and the substrate, the idling process being a process in which polishing of the substrate on the polishing pad does not progress substantially;
obtaining a film thickness data, which varies in accordance with a thickness of the film, by the sensor while performing the idling process; and
calculating a polishing index value indicating the progress of polishing of the film from the film thickness data.

14. The polishing method according to claim 13, wherein the idling process is a process of water-polishing the substrate while supplying the water onto the polishing pad.

15. The polishing method according to claim 13, wherein a time for which the sensor obtains the film thickness data in the idling process is equal to or longer than a time required for paths of the sensor described on the substrate to be distributed evenly in a circumferential direction of the substrate.

16. The polishing method according to claim 15, wherein at least one of a rotational speed of the polishing table and a rotational speed of the substrate is changed in the idling process.

17. The polishing method according to claim 13, wherein calculating said polishing index value comprises calculating an average data of the film thickness data obtained in the idling process and determining the polishing index value from the average data.

18. The polishing method according to claim 13, further comprising:
determining a polishing end point of the substrate based on the polishing index value.

19. The polishing method according to claim 18, wherein determining the polishing end point comprises calculating an additional polishing time required for the polishing index value to reach a predetermined target value.

20. The polishing method according to claim 13, wherein the polishing index value is a film thickness index value indicating the thickness of the film.

21. The polishing method according to claim 13, wherein the polishing index value is an amount of polishing which represents an amount of the film removed by polishing of the substrate.

22. The polishing method according to claim 21, wherein the amount of polishing is determined by calculating an absolute value of a difference between two film thickness data obtained in the idling process and a previous idling process.

23. The polishing method according to claim 13, wherein the sensor is an optical sensor.

24. The polishing method according to claim 13, wherein the sensor is an eddy current sensor.
